(19) United States
(12) Patent Application Publication
(10) Pub. No.: US 2006/0288933 A1
(43) Pub. Date: Dec. 28, 2006

(54) Chemical vapor deposition reactor

(75) Inventors: Stephen Sen-Tien Lee, Taipei (TW); Yury Georgievich Shreter, St Petersburg (RU); Yury Toomasovich Rebane, St Petersburg (RU); Ruslan Ivanovich Gorbunov, St Petersburg (RU)

Correspondence Address: THE WEBB LAW FIRM, P.C., 700 KOPPERS BUILDING, 436 SEVENTH AVENUE, PITTSBURGH, PA, 15219, US

(73) Assignee: Arima Computer Corporation

(21) Appl. No.: 11/167,538

(22) Filed: Jun. 27, 2005

(51) Int. Cl. C23C 16/00

(52) U.S. Cl. 118/715

(57) ABSTRACT

A chemical vapor deposition reactor is provided. The chemical vapor deposition reactor includes a deposition chamber, a substrate within the deposition chamber, at least two inlet ports extending into the deposition chamber for supplying a first and a second gases to the deposition chamber respectively and a particle source for supplying a plurality of solid particles to the deposition chamber. The first gas reacts with the second gas to form a film incorporating the plurality of solid particles upon the substrate. Films with composition varying across the growth direction are produced by the chemical vapor deposition reactor without the use of mask layers.

### FIELD OF THE INVENTION

The present invention relates to a chemical vapor deposition reactor, especially to a chemical vapor deposition reactor with a source of solid particles (CVD-SP).

### BACKGROUND OF THE INVENTION

A chemical vapour deposition (CVD) reactor is commonly used to form a film layer on a chip by the reactor in which a reagent gas reacts to be in a solid phase. After years of improvement, CVD has become the main solution film-forming method among the semiconductor process. The films needed in the semiconductor process, conductor, semiconductor or dielectric, can be formed by CVD.

The conventional CVD reactor allows forming deposition of solid phase films of various structures including epitaxial crystalline, epitaxial polycrystalline, non-epitaxial polycrystalline and amorphous ones. Besides, CVD reactors allow forming deposition of solid phase films with layered structures according to the cases of U.S. Pat. Nos. 6,645,302 and 6,726,767. The thickness of the layers and their composition can be controlled via variation of the reactant gas flows and temperature of the substrate. Thus, CVD reactors allow obtaining planar structures with parameters varying in one direction which is the growth direction. To obtain non-planar structures in CVD process, addition operations of mask layer deposition and window-opening must be applied according to cases of U.S. Pat. Nos. 5,418,183 and 6,728,289.

The need for mask deposition makes the growth process of non-planar structures complicated and expensive.

It is impossible for the traditional chemical vapor deposition reactor to form films with composition varying across the growth direction without the use of mask layers.

### SUMMARY OF THE INVENTION

Hence, for overcoming the mentioned drawbacks in the prior art, the main purpose of the present invention provides a chemical vapor deposition reactor. Films with composition varying across the growth direction are produced by the provided chemical vapor deposition reactor without the use of mask layers.

According to one aspect of the present invention, a chemical vapor deposition reactor is provided. The chemical vapor deposition reactor includes a deposition chamber, a substrate within the deposition chamber, at least two inlet ports extending into the deposition chamber for supplying a first gas and a second gas to the deposition chamber respectively and a particle source for supplying a plurality of solid particles to the deposition chamber. The first gas reacts with the second gas to form a film incorporating the plurality of solid particles upon the substrate.

Preferably, the deposition chamber is arranged vertically or horizontally.

Preferably, the deposition chamber is made of a quartz.

Preferably, the substrate is made of one of a quartz and a sapphire.

Preferably, the chemical vapor deposition reactor further includes a heater for heating the deposition chamber to a temperature at which the first gas reacts with the second gas.

Preferably, the heater is an external heater disposed on the deposition chamber.

Preferably, the heater is an internal heater disposed in the deposition chamber.

Preferably, the first gas is one of GaCl and Ga(CH)₃)₃ (TMG).

Preferably, the second gas is NH₃.

Preferably, the first gas and the second gas are further diluted with N₂ and H₂ respectively.

Preferably, the particle source supplies the plurality of solid particles through a tube into the deposition chamber.

Preferably, the particle source is a container disposed in the deposition chamber.

Preferably, the chemical vapor deposition reactor further includes a piezoelectric driver electrically connected to the container for disturbing the plurality of solid particles.

Preferably, the plurality of solid particles are ones of SiO₂ and a mixture of InGaN and AlGaN.

Preferably, the film further includes a micro-structure or a nano-structure.

According to another aspect of the present invention, a chemical vapor deposition reactor with a solid particle source is provided. As FIG. 1 shows, the chemical vapor deposition reactor includes a horizontal reaction tube 11, an external furnace 12, a substrate 13, an input tube 14 for supplying a first reagent gas, an input tube 15 for supplying a second reagent gas, an input tube 16 for supplying solid particles, a first reagent gas flow 17, a second reagent gas flow 18 and a solid particle flow 19.

In comparison with the traditional chemical vapor deposition reactor, the advantage of the present invention is to grow films of composite material and device structures with composition varying across the rowing direction without the use of mask layers.

The present invention also provides a method of growing films of novel micro-composite and nano-composite materials and device structures with new physical properties and better structural quality.

The foregoing and other features and advantages of the present invention will be more clearly understood through the following descriptions with reference to the drawings, wherein:

### BRIEF DESCRIPTION OF THE DRAWINGS

FIG. 1 is a side view schematically showing a horizontal chemical vapor deposition reactor with an external furnace and a solid-particle-input tube according to the first embodiment of the present invention, which performs a GaN layer by HVPE;

FIG. 2 is a side view schematically showing the GaN films deposited by means of the reactor of FIG. 1;

FIG. 3 is a side view schematically showing a vertical chemical vapor deposition reactor with an external furnace and a solid-particle-input tube according to the second embodiment of the present invention, which performs a GaN layer by HVPE;

FIG. 4 is a side view schematically showing a horizontal chemical vapor deposition reactor with an internal furnace and a solid-particle-input tube according to the third embodiment of the present invention, which performs a GaN layer by MOVPE;

FIG. 5 is a side view schematically showing a horizontal chemical vapor deposition reactor with an internal furnace and a solid particle container above the substrate according to the forth embodiment of the present invention, which performs a GaN layer by MOVPE;

FIG. 6 is a side view schematically showing a horizontal chemical vapor deposition reactor with an internal furnace and a solid-particle-input tube according to the fifth embodiment of the present invention, which performs a GaN layer by MOVPE;

FIG. 7 is a side view schematically showing the GaN films deposited by means of the reactor of FIG. 6;

FIG. 8 is a side view schematically showing a horizontal chemical vapor deposition reactor with an internal furnace and a solid particle container according to the sixth embodiment of the present invention, which performs a GaN layer by MOVPE;

FIG. 9 is a side view schematically showing a horizontal chemical vapor deposition reactor with an internal furnace and a solid particle container below the substrate according to the seventh embodiment of the present invention, which performs a GaN layer by MOVPE; and

FIG. 10 is a side view schematically showing a horizontal chemical vapor deposition reactor with an internal furnace and a solid particle container below the substrate according to the eighth embodiment of the present invention, which performs a GaN layer by MOVPE.

### DETAILED DESCRIPTION OF THE PREFERRED EMBODIMENT

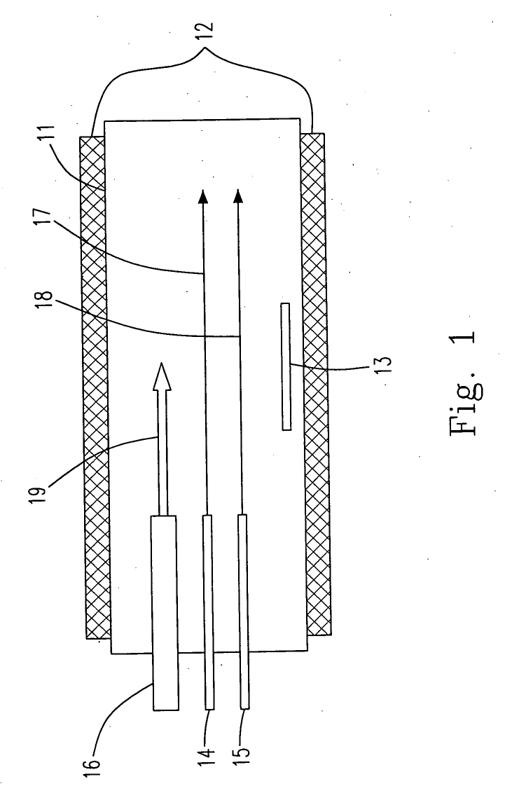

FIG. 1 is a side view schematically showing a horizontal chemical vapor deposition reactor according to the first embodiment of the present invention. In this embodiment, the growth of high quality GaN layers is achieved by hydride vapour phase epitaxy (HVPE). The horizontal chemical vapor deposition reactor includes a quartz horizontal tube 11, an external furnace 12, a sapphire substrate 13, an input tube 14 for supplying a mixture of the first reagent gas GaCl diluted with HCl, N₂ and H₂, an input tube 15 for supplying a mixture of the second reagent gas NH3 diluted with N₂ and H₂ and an input tube 16 of the source of solid particles of SiO₂.

The size of SiO₂ solid particles (d) is in the range of 10⁻⁷˜10⁻³ cm. The small size of solid particles allows themselves to be carried by a carrying gas N₂ or H₂.

The reagent gas flows 17 and 18 form a reactive mixture in the vicinity of the sapphire substrate 13. It causes the growth of a GaN film on the sapphire substrate 13 via the chemical reaction GaCl+NH₃=>GaN+HCl+H₂. The SiO₂ solid particle flow 19 results in the physical absorption of SiO₂ particles on the surface of the growing GaN layer and the further incorporation of inert SiO₂ particles into the GaN film. Thus, the use of the source of SiO₂ solid particles in HVPE growth process allows growing GaN films with the inclusion of nano- or micro- particles of SiO₂.

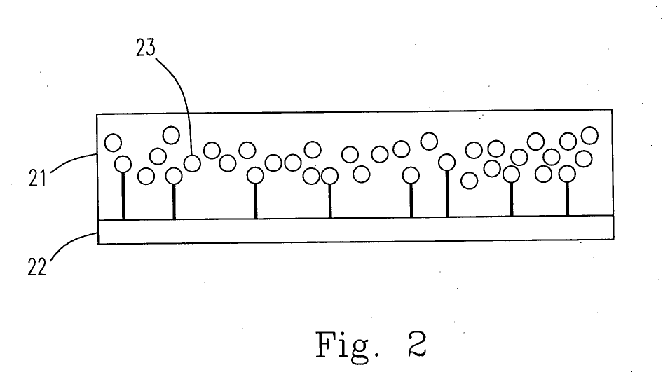

FIG. 2 is a side view schematically showing the GaN films deposited by means of the reactor of FIG. 1. The incorporation into the GaN layer 21, grown on a mismatched sapphire substrate 22 , of nano- or micro- particles 23 of SiO₂, with the surface concentration n ≧1/d^{1/2}, prevents the propagation of threading dislocation along the growth direction and allows improving the structural quality of the GaN films.

Besides, the incorporation of SiO₂ particles into the GaN film in growth process allows growing novel micro-composite or nano-composite materials GaN/SiO₂, which possessed a new physical property. In particular, the variation of the size and the concentration of SiO₂ solid articles in GaN layer allows adjusting its light scattering properties to a given wavelength of the light wave.

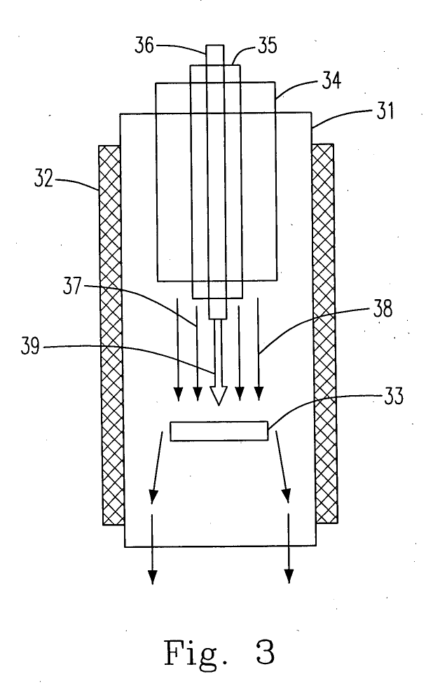

FIG. 3 is a side view schematically showing a vertical chemical vapor deposition reactor according to the second embodiment of the present invention. In this embodiment, the growth of high quality GaN layers is achieved by HVPE. The vertical chemical vapor deposition reactor includes a quartz vertical tube 31, an external furnace 32, a sapphire substrate 33, an input tube 34 for supplying a mixture of the first reagent gas GaCl diluted with HCl, N₂ and H₂, an input tube 35 for supplying a mixture of the second reagent gas NH3 diluted with N₂ and H₂ and an input tube 36 of the source of solid particles of SiO₂.

The size of SiO₂ solid particles (d) is in the range of 10⁻⁷˜10⁻³ cm. The small size of solid particles allows themselves to be carried by a carrying gas N₂ or H₂.

The reagent gas flows 37 and 38 form a reactive mixture in the vicinity of the sapphire substrate 33. It causes the growth of a GaN film on the sapphire substrate 33 via the chemical reaction GaCl+NH₃=>GaN+HCl+H₂. The SiO₂ solid particle flow 39 results in the physical absorption of SiO₂ particles on the surface of the growing GaN layer and the further incorporation of inert SiO₂ particles into the GaN film. Thus, the use of the source of SiO₂ solid particles in HVPE growth process allows growing GaN films with the inclusion of nano- or micro- particles of SiO₂.

Similarly, FIG. 2 is a side view schematically showing the GaN films deposited by means of the reactor of the side view of FIG. 3. The incorporation into the GaN layer 21, grown on a mismatched sapphire substrate 22, of nano- or micro- particles 23 of SiO₂, with the surface concentration n≧1/d^{1/2}, prevents the propagation of threading direction and allows improving the structural quality of the GaN films.

Besides, the incorporation of SiO₂ particles into the GaN film in growth process allows growing novel micro-composite or nano-composite materials GaN/SiO₂, which possessed a new physical property. In particular, the variation of the size and the concentration of SiO₂ solid articles in GaN layer allows adjusting its light scattering properties to a given wavelength of the light wave.

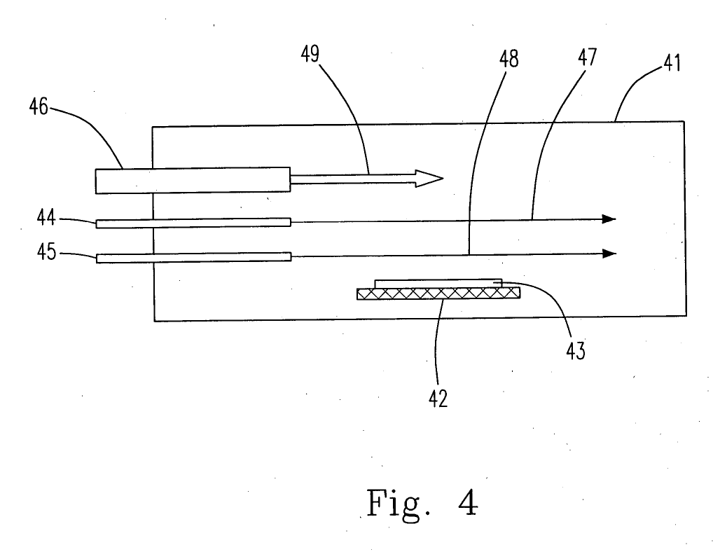

FIG. 4 is a side view schematically showing a horizontal chemical vapor deposition reactor according to the third embodiment of the present invention. In this embodiment, the growth of high quality GaN layers is achieved by metal-organic vapour phase epitaxy (MOVPE). The horizontal chemical vapor deposition reactor includes a quartz horizontal tube 41, an internal furnace 42, a sapphire substrate 43, an input tube 44 for supplying a mixture of the first reagent gas, Ga(CH₃)₃ (TMG) diluted with N₂ and H₂, an input tube 45 for supplying a mixture of the second reagent gas NH3 diluted with N₂ and H₂ and an input tube 46 of the source of solid particles of SiO₂.

The size of SiO₂ solid particles (d) is in the range of 10⁻⁷˜10⁻³ cm. The small size of solid particles allows themselves to be carried by a carrying gas N₂ or H₂.

The reagent gas flows 47 and 48 form a reactive mixture in the vicinity of the sapphire substrate 43. It causes the growth of a GaN film on the sapphire substrate 43 via the chemical reaction Ga(CH₃)₃+NH₃=>GaN+3CH₄. The SiO₂ solid particle flow 49 results in the physical absorption of SiO₂ particles on the surface of the growing GaN layer and the further incorporation of inert SiO₂ particles into the GaN film. Thus, the use of the source of SiO₂ solid particles in MOVPE growth process allows growing GaN films with the inclusion of nano- or micro- particles of SiO₂.

Similarly, FIG. 2 is a side view schematically showing the GaN films deposited by means of the reactor of FIG. 4. The incorporation into the GaN layer 21, grown on a mismatched sapphire substrate 22, of nano- or micro- particles 23 of SiO₂, with the surface concentration n≧1d^{1/2}, prevents the propagation of threading dislocation along the growth direction and allows improving the structural quality of the GaN films.

The incorporation of SiO₂ particles into the GaN film in growth process allows growing novel micro-composite or nano-composite materials GaN/SiO₂, which possessed a new physical property. In particular, the variation of the size and the concentration of SiO₂ solid articles in GaN layer allows adjusting its light scattering properties to a given wavelength of the light wave.

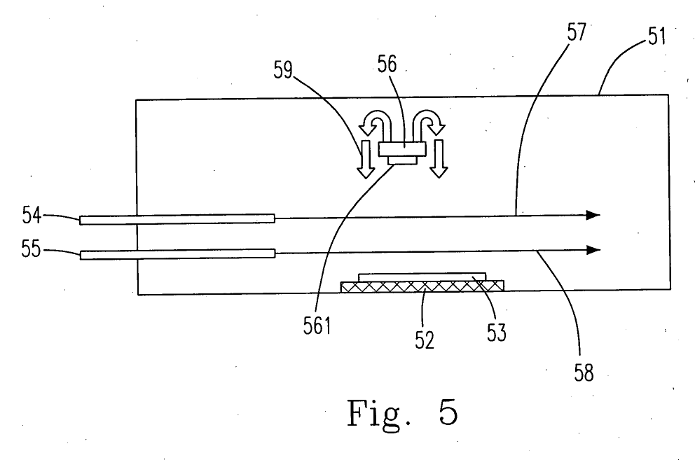

FIG. 5 is a side view schematically showing a horizontal chemical vapor deposition reactor according to the forth embodiment of the present invention. In this embodiment, the growth of high quality GaN layers is achieved by MOVPE. The horizontal chemical vapor deposition reactor includes a quartz horizontal tube 51, an internal furnace 52, a sapphire substrate 53, an input tube 54 for supplying a mixture of the first reagent gas Ga(CH₃)₃ diluted with N₂ and H₂, an input tube 55 for supplying a mixture of the second reagent gas NH3 diluted with N₂ and H₂ and an container 56 of the source of solid particles of SiO₂. The container 56 is equipped with a piezoelectric driver 561.

The size of SiO₂ solid particles is in the range of d=10⁻⁷˜10⁻³ cm. An alterative voltage applied to the piezoelectric driver 561 causes the vibration of the container 56 of solid particles of SiO₂ and results in a gas flow of SiO₂ on the sapphire substrate 53.

The reagent gas flows 57 and 58 form a reactive mixture in the vicinity of the sapphire substrate 53. It causes the growth of a GaN film on the sapphire substrate 53 via the chemical reaction Ga(CH₃)₃+NH₃=>GaN +3CH₄. The SiO₂ solid particle flow 59 results in the physical absorption of SiO₂ particles on the surface of the growing GaN layer and the further incorporation of inert SiO₂ particles into the GaN film. Thus, the use of the source of SiO₂ solid particles in MOVPE growth process allows growing GaN films with the inclusion of nano- or micro- particles of SiO₂.

Similarly, FIG. 2 is a side view schematically showing the GaN films deposited by means of the reactor of FIG. 5. The incorporation into the GaN layer 21, grown on a mismatched sapphire substrate 22, of nano- or micro- particles 23 of SiO₂, with the surface concentration n≧1/d^{1/2}, prevents the propagation of threading dislocation along the growth direction and allows improving the structural quality of the GaN films.

The incorporation of SiO₂ particles into the GaN film in growth process allows growing novel micro-composite or nano-composite materials GaN/SiO₂, which possessed a new physical property. In particular, the variation of the size and the concentration of SiO₂ solid articles in GaN layer allows adjusting its light scattering properties to a given wavelength of the light wave.

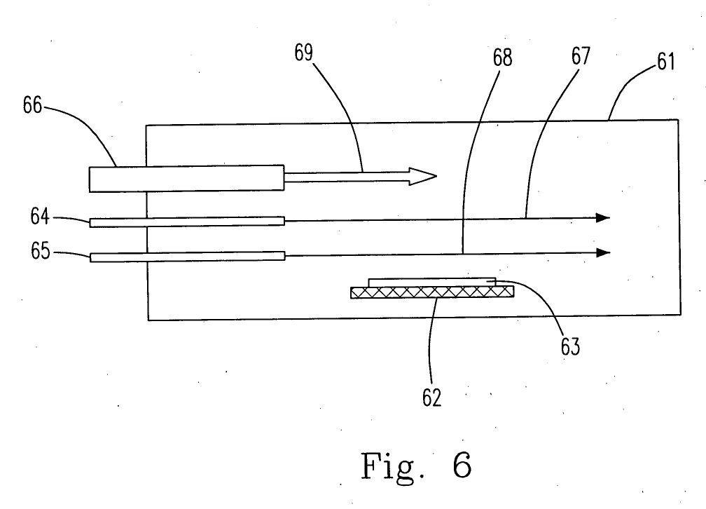

FIG. 6 is a side view schematically showing a horizontal chemical vapor deposition reactor according to the fifth embodiment of the present invention. In this embodiment, the growth of high quality GaN layers is achieved by MOVPE. The horizontal chemical vapor deposition reactor includes a quartz horizontal tube 61, an internal furnace 62, a sapphire substrate 63, an input tube 64 for supplying a mixture of the first reagent gas Ga(CH₃)₃ (TMG) diluted with N₂ and H₂, an input tube 65 for supplying a mixture of the second reagent gas NH3 diluted with N₂ and H₂ and an input tube 66 of a mixture of the source of solid particles InGaN and AlGaN.

The size of solid particles InGaN and AlGaN (d) is in the range of 10⁻⁷˜10⁻³ cm. The small size of solid particles allows themselves to be carried by a carrying gas N₂ or H₂.

The reagent gas flows 67 and 68 form a reactive mixture in the vicinity of the sapphire substrate 63. It causes the growth of a GaN film on the sapphire substrate 63 via the chemical reaction Ga(CH₃)₃+NH₃=>GaN +3CH₄. The InGaN and AlGaN solid particle flow 69 results in the physical absorption of InGaN and AlGaN particles on the surface of the growing GaN layer and the further incorporation of inert InGaN and AlGaN particles into the GaN film. Thus, the use of the source of InGaN and AlGaN solid particles in MOVPE growth process allows growing GaN films with the inclusion of nano- or micro- particles of InGaN and AlGaN.

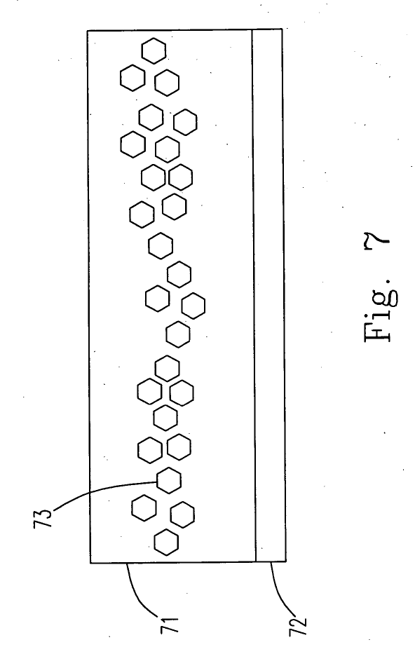

FIG. 7 is a side view schematically showing the GaN films deposited by means of the reactor of FIG. 6. The incorporation into GaN layer 71, grown on the sapphire substrate 72, of nano- or micro- particles 73 of InGaN and AlGaN, results in a composite GaN/AlGaN/InGaN films with laterally varied band gap.

These films are novel micro-composite or nano-composite whose luminescence spectra can be adjusted via variation of the composition and izes of InGaN and AlGaN particles in the mixture entering the input tube 66 in FIG. 6.

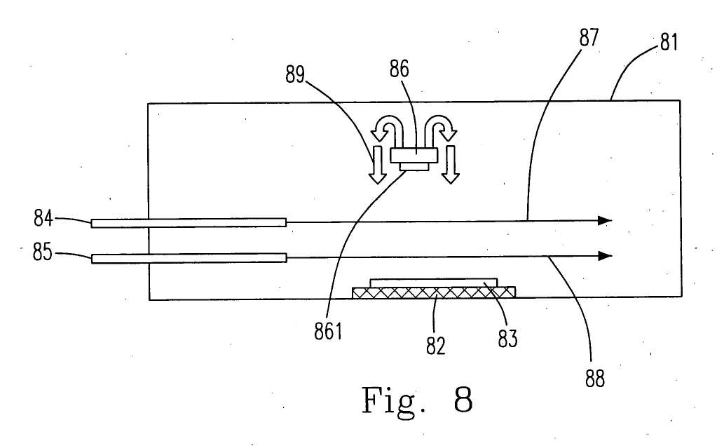

FIG. 8 is a side view schematically showing a horizontal chemical vapor deposition reactor according to the sixth embodiment of the present invention. In this embodiment, the growth of high quality GaN layers is achieved by MOVPE. The horizontal chemical vapor deposition reactor includes a quartz horizontal tube 81, an internal furnace 82, a sapphire substrate 83, an input tube 84 for supplying a mixture of the first reagent gas Ga(CH₃)₃ diluted with N₂ and H₂, an input tube 85 for supplying a mixture of the second reagent gas NH3 diluted with N₂ and H₂ and an container 86 of the source of solid particles of InGaN and AlGaN. The container 86 is equipped with a piezoelectric driver 861.

The size of solid particles InGaN and AlGaN (d) is in the range of 10⁻⁷˜10⁻³ cm. An alterative voltage applied to the piezoelectric driver 861 causes the vibration of the container 86 of solid particles of InGaN and AlGaN and results in a gas flow 89 of InGaN and AlGaN on the sapphire substrate 83.

The reagent gas flows 87 and 88 form a reactive mixture in the vicinity of the sapphire substrate 83. It causes the growth of a GaN film on the sapphire substrate 63 via the chemical reaction Ga(CH₃)₃+NH₃=>GaN+3CH₄. The InGaN and AlGaN solid particle flow 89 results in the physical absorption of InGaN and AlGaN particles on the surface of the growing GaN layer and the further incorporation of inert InGaN and AlGaN particles into the GaN film. Thus, the use of the source of InGaN and AlGaN solid particles in MOVPE growth process allows growing GaN films with the inclusion of nano- or micro- particles of InGaN and AlGaN.

Similarly, FIG. 7 is a side view schematically showing the GaN films deposited by means of the reactor of FIG. 8. The incorporation into GaN layer 71, grown on the sapphire substrate 72, of nano- or micro- particles 73 of InGaN and AlGaN, results in a composite GaN/AlGaN/InGaN films with laterally varied band gap.

These films are novel micro-composite or nano-composite whose luminescence spectra can be adjusted via variation of the composition and izes of InGaN and AlGaN particles in the mixture entering the input tube 66 in FIG. 6.

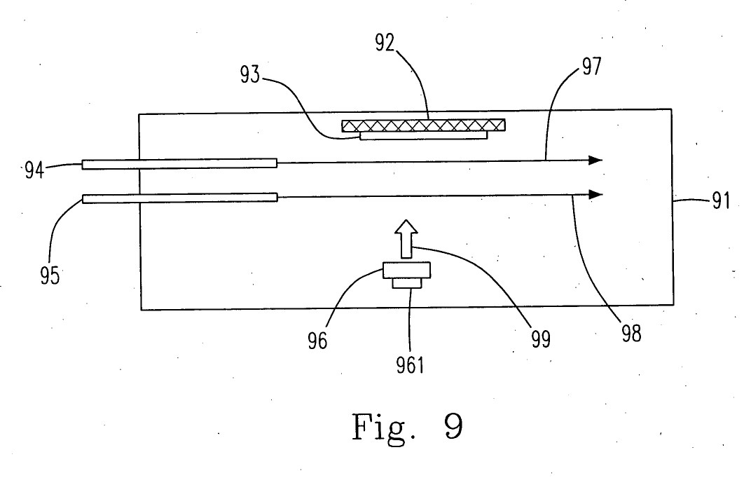

FIG. 9 is a side view schematically showing a horizontal chemical vapor deposition reactor according to the seventh embodiment of the present invention. In this embodiment, the growth of high quality GaN layers is achieved by MOVPE. The horizontal chemical vapor deposition reactor includes a quartz horizontal tube 91, an internal furnace 92, a sapphire substrate 93, an input tube 94 for supplying a mixture of the first reagent gas Ga(CH₃)₃ diluted with N₂ and H₂, an input tube 95 for supplying a mixture of the second reagent gas NH3 diluted with N₂ and H₂ and an container 96 of the source of solid particles of SiO₂. The container 96 is equipped with a piezoelectric driver 961.

The difference between this embodiment (FIG. 9) and the forth embodiment (FIG. 5) is that the sapphire substrate 93 is above the container 96.

The size of solid particles SiO₂ (d) is in the range of 10⁻⁷˜10⁻³ cm. An alterative voltage applied to the piezoelectric driver 961 causes the vibration of the container 96 of solid particles of SiO₂ and results in a gas flow 99 of SiO₂ on the sapphire substrate 93.

FIG. 2 is a side view schematically showing the GaN films deposited by means of the reactor of FIG. 9. The incorporation into the GaN layer 21, grown on a mismatched sapphire substrate 22 , of nano- or micro- particles 23 of SiO₂, with the surface concentration n≧1/d^{1/2}, prevents the propagation of threading dislocation along the growth direction and allows improving the structural quality of the GaN films.

The incorporation of SiO₂ particles into the GaN film in growth process allows growing novel micro-composite or nano-composite materials GaN/SiO₂, which possessed a new physical property. In particular, the variation of the size and the concentration of SiO₂ solid articles in GaN layer allows adjusting its light scattering properties to a given wavelength of the light wave.

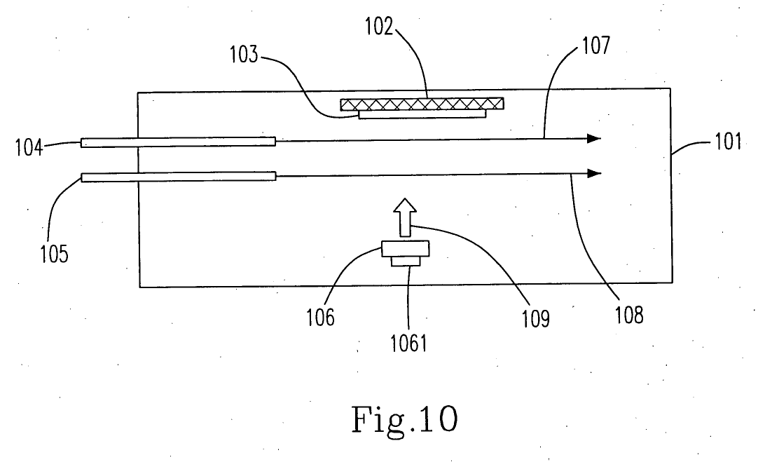

FIG. 10 is a side view schematically showing a horizontal chemical vapor deposition reactor according to the eighth embodiment of the present invention. In this embodiment, the growth of high quality GaN layers is achieved by MOVPE. The horizontal chemical vapor deposition reactor includes a quartz horizontal tube. 101, an internal furnace 102, a sapphire substrate 103, an input tube 104 for, supplying a mixture of the first reagent gas Ga(CH₃)₃ diluted with N₂ and H₂, an input tube 105 for supplying a mixture of the second reagent gas NH3 diluted with N₂ and H₂ and an container 106 of the source of solid particles of InGaN and AlGaN. The container 106 is equipped with a piezoelectric driver 1061.

The difference between this embodiment (FIG. 10) and the sixth embodiment (FIG. 8) is that the sapphire substrate 103 is above the container 106.

The reagent gas flows 107 and 108 form a reactive mixture in the vicinity of the sapphire substrate 103. It causes the growth of a GaN film on the sapphire substrate 103 via the chemical reaction Ga(CH₃)₃+NH₃=>GaN+3CH₄. The InGaN and AlGaN solid particle flow 109 results in the physical absorption of InGaN and AlGaN particles on the surface of the growing GaN layer and the further incorporation of inert InGaN and AlGaN particles into the GaN film. Thus, the use of the source of InGaN and AlGaN solid particles in MOVPE growth process allows growing GaN films with the inclusion of nano- or micro- particles of InGaN and AlGaN.

Similarly, FIG. 7 is a side view schematically showing the GaN films deposited by means of the reactor of FIG. 10. The incorporation into GaN layer 71, grown on the sapphire substrate 72 , of nano- or micro- particles 73 of InGaN and AlGaN, results in a composite GaN/AlGaN/InGaN films with laterally varied band gap.

These films are novel micro-composite or nano-composite whose luminescence spectra can be adjusted via variation of the composition and izes of InGaN and AlGaN particles in the mixture entering the input tube 106 in FIG. 10.

The present invention provides a chemical vapor deposition reactor. A source of solid particles is added into the traditional deposition chamber. In the deposition chamber, the main reagent gases mix each other and react by MOVPE or HVPE under a proper temperature and a film including the solid particles is then formed on the substrate in the deposition chamber.

The chemical vapor deposition reactor with the solid particle source allows the deposition of the host material film on the substrate from gas phase via a chemical reaction between reactant gases and the incorporation of particles of foreign materials into the film via physical absorption of particles on the surface of the growing film.

The incorporation of particles into the host material growing from gas phase allows obtaining layers with composition varying across the growing direction.

In comparison with the conventional chemical vapor deposition reactor, films with composition varying across the growth direction are produced by the chemical vapor deposition reactor without the use of mask layers. The structures of the films are of micro-composite or nano-composite with novel physical properties and better quality.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded, with the broadest interpretation so as to encompass all such modifications and similar structures.

What is claimed is:

1. A chemical vapor deposition reactor comprising:
a deposition chamber;
a substrate within said deposition chamber;
at least two inlet ports extending into said deposition chamber for supplying a first and a second gases to said deposition chamber, respectively; and
a particle source for supplying a plurality of solid particles to said deposition chamber;
wherein said first gas reacts with said second gas to form a film incorporating said plurality of solid, particles upon said substrate.

2. The chemical vapor deposition reactor as claimed in claim 1, wherein said deposition chamber is arranged vertically.

3. The chemical vapor deposition reactor as claimed in claim 1, wherein said deposition chamber is arranged horizontally.

4. The chemical vapor deposition reactor as claimed in claim 1, wherein said deposition chamber is made of a quartz.

5. The chemical vapor deposition reactor as claimed in claim 1, wherein said substrate is made of one of a quartz and a sapphire.

6. The chemical vapor deposition reactor as claimed in claim 1, further comprising a heater for heating said deposition chamber to a temperature at which said first gas reacts with said second gas.

7. The chemical vapor deposition reactor as claimed in claim 6, wherein said heater is an external heater disposed on said deposition chamber.

8. The chemical vapor deposition reactor as claimed in claim 6, wherein said heater is an internal heater disposed in said deposition chamber.

9. The chemical vapor deposition reactor as claimed in claim 6, wherein said first gas is one of GaCl and Ga(CH)₃)₃ (TMG).

10. The chemical vapor deposition reactor as claimed in claim 6, wherein said second gas is NH₃.

11. The chemical vapor deposition reactor as claimed in claim 1, wherein said first gas and said second gas are further diluted with N₂ and H₂, respectively.

12. The chemical vapor deposition reactor as claimed in claim 1, wherein said particle source supplies said plurality of solid particles through a tube into said deposition chamber.

13. The chemical vapor deposition reactor as claimed in claim 1, wherein said particle source is a container disposed in said deposition chamber.

14. The chemical vapor deposition reactor as claimed in claim 1, further comprising a piezoelectric driver electrically connected to said container for disturbing said plurality of solid particles.

15. The chemical vapor deposition reactor as claimed in claim 1, wherein said plurality of solid particles are ones of SiO₂ and a mixture of InGaN and AlGaN.

16. The chemical vapor deposition reactor as claimed in claim 1, wherein said film further comprises a micro-structure.

17. The chemical vapor deposition reactor as claimed in claim 1, wherein said film further comprises a nano-structure.
